(19) United States
(12) Patent Application Publication
(10) Pub. No.: US 2010/0015744 A1
(43) Pub. Date: Jan. 21, 2010

(54) Micro-Electromechanical Device and Method of Making the Same

(75) Inventor: Robert Kazinzci, Helmond (NL)

Correspondence Address: PATTERSON & SHERIDAN, L.L.P., 3040 POST OAK BOULEVARD, SUITE 1500, HOUSTON, TX, 77056, US

(73) Assignee: CAVENDISH KINETICS LTD.

(21) Appl. No.: 12/085,429

(22) PCT Filed: Nov. 22, 2006
(86) PCT No.: PCT/GB2006/004354

§ 371 Date: May 22, 2008

(30) Foreign Application Priority Data
Nov. 22, 2005 (GB) 0523715.1

(51) Int. Cl. H01L 21/28; H01L 21/306

(52) U.S. Cl. 438/52; 257/E21.158; 257/E21.215

(57) ABSTRACT

A method of manufacturing a cantilever-based micro-electromechanical device comprising the steps of providing a first conductive material layer on a substrate to from a plurality of electrodes. Then, depositing a sacrificial material layer on the electrodes and substrate, thereby defining a non-exposed surface and an exposed surface of the sacrificial material. The method comprises the steps of patterning and etching the sacrificial material layer such that at least a portion of at least one electrode is exposed and spuner etching the sacrificial material layer such that the exposed surface of the sacrificial material layer comprises edges which are incongruous with the edges of the non-exposed surface. The method then involves forming a cantilever structure. Finally, the method comprises the step of removing at least a portion of the sacrificial material layer such that at least a portion of the cantilever structure is suspended.

The present invention relates to controlling the contact area of cantilever-based micro-electromechanical devices for use in, for example, semiconductor device technology.

A significant problem impeding the progress of micro-electromechanical devices (MEMS) is the propensity for cantilever structures to “stick” to electrode(s) or electrodes to stick to one another upon contact, making it difficult to separate the surfaces. The adhesive forces behind this phenomenon are generally and collectively known as “stiction”. Stiction refers to various forces tending to make two surfaces adhere to each other. Such forces include Van der Waals forces, surface tension caused by moisture between surfaces and bonding between surfaces (e.g. through metallic diffusion).

One solution to the problem of stiction is to provide MEMS devices which are made of materials having high spring constants. When, under the effect of electromagnetic forces, the cantilever structures of these MEMS devices are bowed in order to be brought into contact with an electrode so as to, for example, close a switch, the bending of the material creates a restorative force in the device that naturally seeks to break the contact between the surface of the device and the surface of the electrode. Such a force, if sufficient in magnitude, can overcome the effects of stiction. However, devices using this approach have poor scalability in that, the smaller a cantilever structure becomes, the less resilient is becomes.

A first solution to this problem has been sought in the application of thin (often mono-layer) coatings to the contact area of the cantilever structure and/or the electrode, thereby reducing the surface contact between the two elements. However, this solution provides a serious disadvantage in that these surface coatings are non-conductive and therefore prevent the transfer of charge from one element to another. They are therefore not suitable for applications requiring charge transfer.

A second solution to this problem has been sought in what is known as “bump technology”. This method involves the step of patterning and etching a protrusion on the surface of an electrode which is to come into contact with a cantilever structure. Although this does solve the problem of controlling the contact area between the cantilever structure and the electrode, it requires an extra masking step in the fabrication process. This will add to the complexity and the cost involved in manufacturing the MEMS device.

There is therefore a clear need for a method of manufacturing a cantilever-based MEMS device where the contact area between the cantilever structure and the contact electrode can be controlled, without the need for extra masking steps and without the need to degrade the conductivity of the contact area.

In order to solve the problems associated with the prior art, the present invention provides a method of manufacturing a cantilever-based micro-electromechanical device, the method comprises the steps of:

providing a first conductive material layer on a substrate;

patterning and etching the first conductive material layer to from a plurality of electrodes;

depositing a sacrificial material layer on the electrodes and substrate, thereby defining a non-exposed surface of the sacrificial material layer, the non-exposed surface of the sacrificial material layer adjoining the plurality of electrodes and an exposed surface of the sacrificial material, the exposed surface of the sacrificial material layer being opposed to the non-exposed surface of the sacrificial material layer;

patterning and etching the sacrificial material layer such that at least a portion of at least one electrode is exposed;

sputter etching the sacrificial material layer such that the exposed surface of the sacrificial material layer comprises edges which are incongruous with the edges of the non-exposed surface of the sacrificial material layer;

depositing a second conducting material layer on the at least one exposed electrode and exposed surface of the sacrificial material layer;

patterning and etching the second conducting material layer in order to form a cantilever structure;

removing at least a portion of the sacrificial material layer such that at least a portion of the cantilever structure is suspended.

Preferably, the sacrificial material layer is an etchable material layer.

Preferably, the first and second conducting layers are formed from a group of materials selected from Nickel, Copper, Chromium, Cobalt, Zinc, Iron, Titanium, Aluminum, Tantalum, Ruthenium Platinum and Cobalt, including their alloys or compounds.

Preferably, the first and second conducting layers are made from titanium nitride or tantalum nitride.

Preferably, the sacrificial material layer is made form silicon-based materials or carbon-based materials.

Preferably, silicon based materials include silicon-nitride, amorphous silicon, silicon oxide and a spin on glass material.

Preferably, carbon based materials include amorphous carbon or polyimide

Preferably, the step of removing at least a portion of the sacrificial material layer further comprises the step of:

etching at least a portion of the sacrificial material layer using a nitrogen trifluoride or sulphur hexafluroide in an RF or microwave plasma etching process.

Preferably, the step of removing at least a portion of the sacrificial material layer further comprises the step of:

etching at least a portion of the sacrificial material layer using oxygen in a plasma etching process.

As will be appreciated by a person skilled in the art, the present invention provides several advantages over the prior art. First of all, the present invention provides a method of controlling the contact area between a cantilever structure and an electrode which does not require any extra masking steps. Moreover, the contact area of the present invention will not be adversely affected by any non-conductive thin films. Therefore, the device of the present invention can be used in applications such as radio frequency switches, micro relays and memory.

Examples of the present invention will now be described with reference to the accompanying drawings, in which:

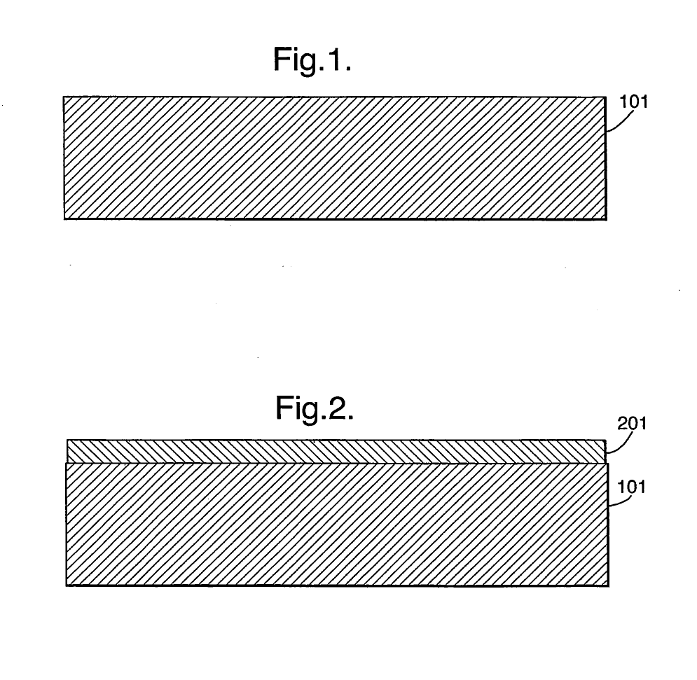

FIG. 1 shows a cross-section of a substrate;

FIG. 2 shows a cross-section of the substrate of FIG. 1, where a metal layer is deposited thereon;

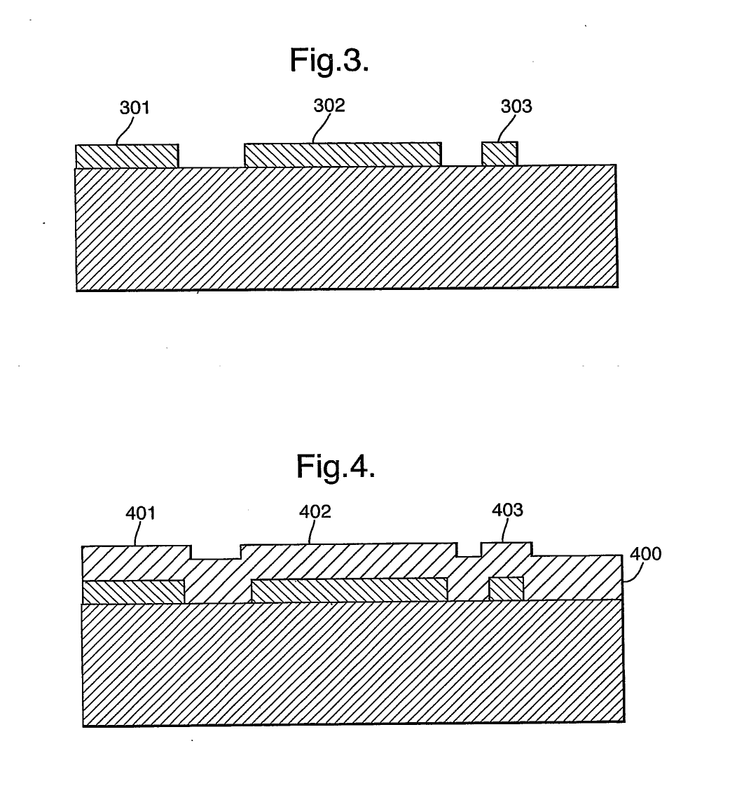

FIG. 3 shows a cross-section of the substrate of FIG. 2, where the metal layer is patterned and etched;

FIG. 4 shows a cross-section of the substrate of FIG. 3, where a sacrificial layer is deposited thereon and then patterned and etched;

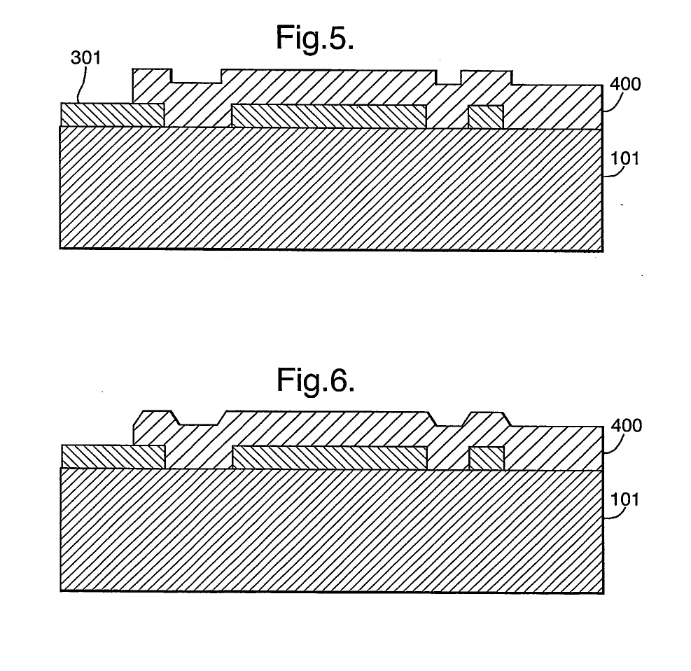

FIG. 5 shows a cross-section of the substrate of FIG. 4, where the sacrificial layer is further etched to expose part of an electrode;

FIG. 6 shows a cross-section of the substrate of FIG. 5, where the sacrificial layer is selectively etched;

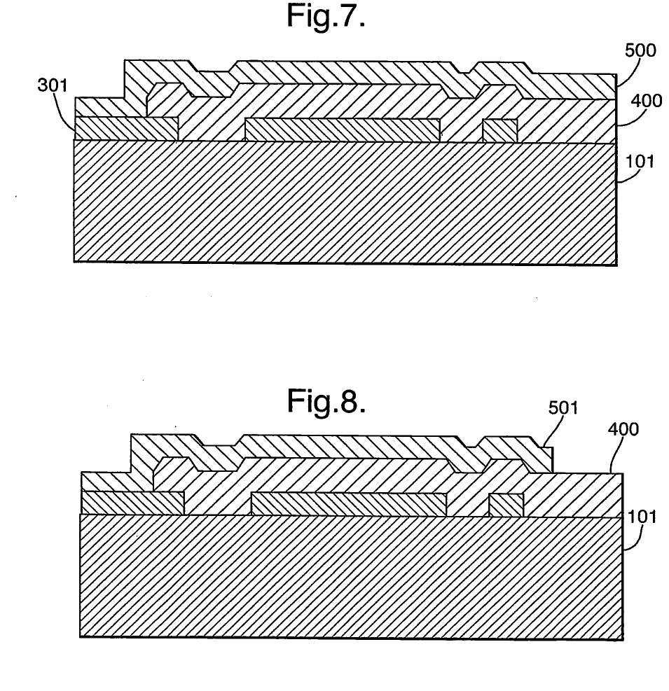

FIG. 7 shows a cross-section of the substrate of FIG. 6, where a further metal layer has been provided over the sacrificial layer;

FIG. 8 shows a cross-section of the substrate of FIG. 7, where the metal layer has been selectively patterned and etched;

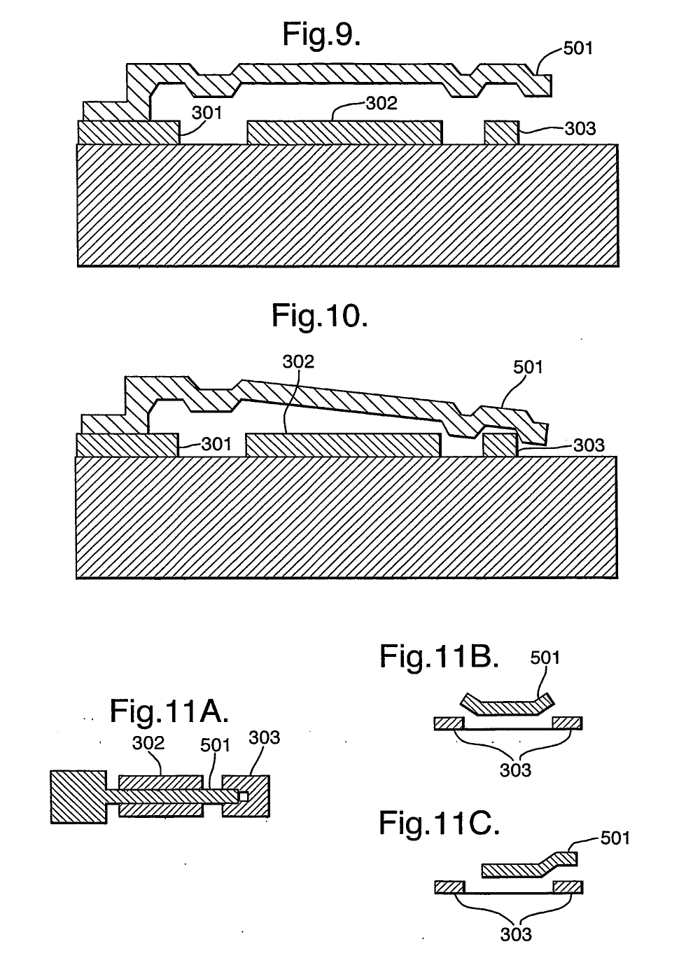

FIG. 9 shows a cross-section of the substrate of FIG. 8, where the sacrificial material layer has been removed;

FIG. 10 shows a cross-section of the device of the present invention, in operation;

FIG. 11a shows a plan view of the device having an electrode with a selective opening;

FIG. 11b shows an end view of the tip of device indicating the points of contact of the structural element with the electrode;

FIG. 11c shows an end view of the tip of device indicating where a misaligned structural element makes contact with the electrode.

With reference to FIGS. 1 to 9, the method of the present invention will now be described. FIG. 1 shows a cross-section of a substrate 100 upon which a cantilever-based micro-electromechanical system device is to be provided. FIG. 2 shows a cross-section of the substrate 100 of FIG. 1, where a conducting layer 201 is deposited thereon. The conducting layer can be formed from a group of materials selected from Nickel, Copper, Chromium Cobalt, Zinc Iron, Titanium Aluminum, Tantalum Ruthenium, Platinum or Cobalt, including their alloys or compounds. Preferably, the conducting layer is made from titanium nitride or tantalum nitride.

Now, in reference to FIG. 3, the conducting layer 201 is patterned and etched into a first electrode 301, a second electrode 302 and a third electrode 303. The three electrodes will act as the three terminals of the cantilever device. The first electrode 301 will be directly connected to the cantilever structure itself, the second electrode 302 will act as a “pull-in” electrode which will generate the electromagnetic force necessary to pull the cantilever structure towards it and the third electrode 303 will act as a contact electrode which will come into contact with the free end of the cantilever structure, thereby permitting a transfer of charge there between.

FIG. 4 shows the substrate 101 and electrodes 301, 302, 303 of FIG. 3 where a layer of sacrificial material 400 has been deposited thereon. The sacrificial layer 400 may be made from silicon-based materials or carbon-based materials. If the sacrificial layer is made from silicon-based materials, these materials can be selected from a group of materials comprising silicon-nitride, amorphous silicon, silicon oxide and spin-on-glass materials.

Referring to both FIGS. 3 and 4, because the sacrificial material is uniformly distributed over the surface formed by the upper and side surfaces of the electrodes 301, 302 and 303 and the exposed surfaces of the substrate 101, the upper surface of the sacrificial material will effectively have the same shape. Accordingly, the protrusion created by electrode 301 will create a similar protrusion 401 on the top surface of the sacrificial layer 400, the protrusion created by electrode 302 will create a similar protrusion 402 on the top surface of the sacrificial layer 400 and the protrusion created by electrode 303 will create a similar protrusion 403 on the top surface of the sacrificial layer 400.

As can be seen in FIGS. 3 and 4, were a further layer of material to be directly deposited on the layer of sacrificial material 400, that layer of material would fill the gaps between protrusions 401 and 402 and between 402 and 403, thereby creating a layer which, were the sacrificial layer 400 to be removed, would physically fit in the gaps between electrodes 301, 302 and 303. The present invention seeks to reduce the congruence between these two surfaces and thereby diminish the possible contact area between the free end of the cantilever structure and the second and third electrodes 302 and 303.

With reference to FIG. 5, the sacrificial layer 400 is patterned and etched such that at least a part of the first electrode 301 is exposed. This will permit the next layer of conductive material to bond with the first electrode 301, thereby forming a cantilever terminal of the device.

Now, with reference to FIG. 6, before a further layer of conductive material is deposited, the edges of the protrusions 401, 402 and 403 are bevelled using sputter etching. Alternatively, other changes in the upper surface of the sacrificial layer 400 can be made so as to reduce the gap between the bottom surface of the cantilever structure and the surface formed by the top and side surface of the second and third electrodes 302 and 303 compared with the gap between the bottom surface of the cantilever and the exposed surface of the substrate layer 101.

With reference to FIG. 7, the next step in the method consists of depositing a second layer of conductive material 500 over the etched layer of sacrificial material 400. The conducting layer can be formed from a group of materials selected from Nickel, Copper, Chromium Cobalt, Zinc Iron, Titanium Aluminum, Tantalum Ruthenium, Platinum or Cobalt, including their alloys or compounds. Preferably, the conducting layer is made from titanium nitride or tantalum nitride. As stated above, the second layer of conductive material 500 will fill in the gaps between the protrusions 401, 402 and 403 and will also fill in any area which was etched away in the sputter etching step. Moreover, the second layer of conductive material will in part be deposited directly on at least a portion of the first electrode 301, thereby insuring electrical conduction there between.

FIG. 8 shows a cross-section of the substrate of FIG. 7, where the conductive layer 500 has been patterned and etched in order to form a cantilever structure 501.

The next step in the method is the removal of the sacrificial layer 400. This step may include using a fluorine source gas, preferably nitrogen trifluoride or sulphur hexafluoride in an etching process or an RF or microwave plasma etching process. Removing at least a portion of the sacrificial layer may include using oxygen gas in a plasma etching process. FIG. 9 shows the device where the sacrificial layer 400 has been removed. The device manufactured according to the method of the present invention may also be encapsulated by a further layer.

Now, with reference to FIG. 10, the operation of the device will now be described. When a voltage is applied between the first electrode 301 and the second electrode 302, an electromagnetic force will be created which will draw the cantilever structure 501 towards the second electrode 302. As the cantilever structure 501 bends towards the second electrode 302, it will come into contact with the third electrode 303. When this happens, because the bottom surface of the cantilever structure 501 is not of the same shape (i.e. congruent) as that of the surface formed by the side and top surfaces of the second and third electrode and the exposed surfaces of the substrate, surface contact between the cantilever structure 501 and the third electrode 303 will be minimised.

Accordingly, the cantilever structure of the present invention will be permitted to contact the third electrode 303, allowing a transfer of charge to take place, but will not be permitted to directly adjoin or entirely cover the third electrode 303, thereby minimising (or otherwise controlling) the effects of stiction forces without the need for extra masking steps in the process.

FIG. 11a shows a top view of the cantilever structure 501 and the two electrodes 302 and 303. Electrode 303 has “U” shape as viewed from the top. The cantilever 501 width is wider than the spacing between the two lateral portions of the “U”.

FIGS. 11b and 11c show a cross-section view through the end of the cantilever perpendicular to the plane of the substrate and the longitudinal direction of the cantilever 501. FIGS. 11b and 11c also clearly show that, despite some lateral misalignment between the cantilever and the electrode 303, a small contact will always be made first between the underside of the cantilever and one corner of one of the other lateral side of the “U”-shaped structure. Thus, the contact area may be minimised.

1. A method of manufacturing a cantilever-based micro-electromechanical device, the method comprising the steps of:
providing a first conductive material layer on a substrate;
pattering and etching the first conductive material layer to form a plurality of electrodes;
depositing a sacrificial material layer on the electrodes and substrate, thereby defining a non-exposed surface of the sacrificial material layer, the non-exposed surface of the sacrificial material layer adjoining the plurality of electrodes and an exposed surface of the sacrificial material layer, the exposed surface of the sacrificial material layer being opposed to the non-exposed surface of the sacrificial material layer;
patterning and etching the sacrificial material layer such that at least a portion of at least one electrode is exposed;
sputter etching the sacrificial material layer such that the exposed surface of the sacrificial material layer comprises edges which are incongruous with the edges of the non-exposed surface of the sacrificial material layer;
depositing a second conducting material layer on the at least one exposed electrode and exposed surface of the sacrificial material layer;
patterning and etching the second conducting material layer in order to form a cantilever structure;
removing at least a portion of the sacrificial material layer such that at least a portion of the cantilever structure is suspended.

2-9. (canceled)

10. The method of claim 1, wherein the sacrificial material layer is an etchable material layer.

11. The method of claim 1, wherein the first and second conducting layers are formed from a group of materials selected from nickel, copper, chromium cobalt, zinc, iron, titanium, aluminum, tantalum, ruthenium, platinum, and cobalt.

12. The method of claim 1, wherein the first and second conducting layers are made from titanium nitride.

13. The method of claim 1, wherein the first and second conducting layers comprise tantalum nitride.

14. The method of claim 1, wherein the sacrificial material layer comprises silicon-based materials.

15. The method of claim 1, wherein the sacrificial material layer comprises carbon-based materials.

16. The method of claim 1, wherein the step of removing at least a portion of the sacrificial material layer further comprises the step of:
etching at least a portion of the sacrificial material layer using nitrogen trifluoride in an RF plasma etching process.

17. The method of claim 1, wherein the step of removing at least a portion of the sacrificial material layer further comprises the step of:
etching at least a portion of the sacrificial material layer using sulphur hexafluoride in an RF plasma etching process.

18. The method of claim 1, wherein the step of removing at least a portion of the sacrificial material layer further comprises the step of:
etching at least a portion of the sacrificial material layer using oxygen in a plasma etching process.
